(19) United States
(12) Patent Application Publication
(10) Pub. No.: US 2018/0172758 A1
(43) Pub. Date: Jun. 21, 2018

(54) VOLTAGE MONITORING CIRCUIT AND SEMICONDUCTOR DEVICE

(71) Applicant: Renesas Electronics Corporation, Tokyo (JP)

(72) Inventor: Issei KASHIMA, Tokyo (JP)

(21) Appl. No.: 15/729,779

(22) Filed: Oct. 11, 2017

(30) Foreign Application Priority Data
Dec. 16, 2016 (JP) 2016-243988

(51) Int. Cl. G01R 31/28; H01L 23/58

(52) U.S. Cl. CPC G01R 31/2836; H01L 23/58

(57) ABSTRACT

A voltage monitoring circuit and a semiconductor device that can reduce time required for self-diagnosis are provided. A selection circuit selects one of a determination threshold voltage for normal use, a determination threshold voltage for self-diagnosis, and a determination threshold voltage for boost having a potential difference larger than that of the determination threshold voltage for normal use. A comparison circuit detects a presence or absence of a specification violation of the voltage to be monitored by comparing a selected voltage selected by the selection circuit and the voltage to be monitored. Here, the selection circuit forcibly outputs a detection result indicating that there is a specification violation by defining the determination threshold voltage for normal use as an initial state and sequentially selecting the determination threshold voltage for self-diagnosis, the determination threshold voltage for boost, and the determination threshold voltage for normal use when the self-diagnosis is performed.

### CROSS-REFERENCE TO RELATED APPLICATIONS

The disclosure of Japanese Patent Application No. 2016-243988 filed on Dec. 16, 2016 including the specification, drawings and abstract is incorporated herein by reference in its entirety.

### BACKGROUND

The present invention relates to a voltage monitoring circuit and a semiconductor device and, for example, relates to a voltage monitoring circuit and a semiconductor device which are equipped with a self-diagnosis function.

For example, Japanese Unexamined Patent Application Publication No. 2007-315933 discloses a comparator circuit that detects a transition of zero to plus of a potential difference of two inputs by a small operating current (low consumption current) when cancelling power down based on LVDS (Low Voltage Differential Signaling) and quickly detects a subsequent transition from plus to minus by a large operating current.

### SUMMARY

In recent years, lowering of voltage of semiconductor devices is advanced. Accordingly, an operating margin of semiconductor device with respect to variation of power supply voltage and the like decreases, and it is required to control the variation of power supply voltage and the like within a small range. Therefore, a semiconductor device may be mounted with a voltage monitoring circuit that monitors variation of power supply voltage and the like and an error processing circuit or the like that performs predetermined error processing when an abnormality is detected by the voltage monitoring circuit.

On the other hand, for example, a semiconductor device that requires reliability, which is typically represented by a semiconductor device for vehicle use, may be provided with a self-diagnosis function for diagnosing whether or not the voltage monitoring circuit and the error processing circuit described above operate normally as one of safety functions. As one of methods for realizing the self-diagnosis function, a method is considered that forcibly applies a potential difference that causes an abnormality to a comparison circuit included in the voltage monitoring circuit and thereafter returns the potential difference to the original potential difference.

However, the inventors have found that such a method has a risk that the time required for the self-diagnosis increases. Specifically, there is a risk of requiring a long time to restore the voltage monitoring circuit to a normal operation state by returning the potential difference to a normal potential difference (that is, to restore the voltage monitoring circuit from a state where an abnormality is detected to a state where no abnormality is detected). As described above, the smaller the control range of the power supply voltage and the like and accordingly the smaller the normal potential difference, the longer the time to restore the voltage monitoring circuit.

Embodiments described later have been made in view of the above problem, and the other problems and novel features will become apparent from the description of the present specification and the accompanying drawings.

A voltage monitoring circuit according to an embodiment has a selection circuit and a comparison circuit, detects a presence or absence of a specification violation of a voltage to be monitored by comparing the voltage to be monitored with a first determination threshold voltage, and can forcibly output a detection result indicating that there is a specification violation when a self-diagnosis is performed. The selection circuit selects any one of the first determination threshold voltage, a second determination threshold voltage that is a voltage having a polarity reverse to that of the first determination threshold voltage with reference to the voltage to be monitored, and a third determination threshold voltage that is a voltage having the same polarity as that of the first determination threshold voltage and has a potential difference larger than that of the first determination threshold voltage. The comparison circuit detects the presence or absence of the specification violation by comparing a selected voltage selected by the selection circuit and the voltage to be monitored. When the self-diagnosis is performed, the selection circuit defines the first determination threshold voltage as an initial state and sequentially selects the second, the third, and the first determination threshold voltages.

According to the embodiment described above, it is possible to reduce the time required for the self-diagnosis.

### BRIEF DESCRIPTION OF THE DRAWINGS

FIG. 1A is a schematic diagram showing a configuration example of a voltage monitoring circuit according to a first embodiment of the present invention.

FIG. 1B is a schematic diagram showing an operation example of a self-diagnosis in the voltage monitoring circuit of FIG. 1A.

FIG. 2 is a schematic diagram showing an operation example different from that of FIG. 1B.

FIG. 3 is a schematic diagram showing a configuration example obtained by expanding the voltage monitoring circuit of FIG. 1A.

FIG. 4 is a circuit diagram showing a detailed configuration example around the voltage monitoring circuit of FIG. 1A.

FIG. 5 is a schematic diagram showing a configuration example of a semiconductor device according to the first embodiment of the present invention.

FIG. 6 is a schematic diagram showing an example of a problem that may occur when using the voltage monitoring circuit of FIG. 4.

FIG. 7 is a circuit diagram showing a detailed configuration example around a voltage monitoring circuit according to a second embodiment of the present invention.

FIG. 8 is a pattern diagram showing an example of a size relationship of main transistors in the voltage monitoring circuit of FIG. 7.

FIG. 9A is a schematic diagram showing a configuration example of a voltage monitoring circuit according to a third embodiment of the present invention.

FIG. 9B is a schematic diagram showing an operation example of a self-diagnosis in the voltage monitoring circuit of FIG. 9A.

FIG. 10 is a circuit diagram showing a detailed configuration example of the voltage monitoring circuit of FIG. 9A.

FIG. 11A is a schematic diagram showing a configuration example of a voltage monitoring circuit studied as a comparative example of the present invention.

FIG. 11B is a schematic diagram showing an operation example of a self-diagnosis in the voltage monitoring circuit of FIG. 11A.

FIG. 12 is a circuit diagram showing a configuration example of a comparison circuit in the voltage monitoring circuit of FIG. 11A.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. In the following embodiments, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically.

Furthermore, in the following embodiments, it is needless to say that an element (including an element step etc.) is not necessarily indispensable, except for the case where it is clearly specified in particular and where it is considered to be clearly indispensable from a theoretical point of view, etc. Similarly, in the following embodiments, when shape, position relationship, etc. of an element etc. are referred to, what resembles or is similar to the shape, etc. substantially shall be included, except for the case where it is clearly specified in particular and where it is considered to be clearly not right from a theoretical point of view. This statement also applies to the numeric value and range described above.

While a circuit element that forms each functional block of the embodiments is not limited in particular, the circuit element is formed over a semiconductor substrate such as single-crystal silicon by an integrated circuit technique such as a publicly known CMOS (Complementary MOS transistor) technique. In the embodiments, a MOSFET (Metal Oxide Semiconductor Field Effect Transistor) (abbreviated as MOS transistor) is used as an example of a MISFET (Metal Insulator Semiconductor Field Effect Transistor). However, a non-oxide film is not excluded as agate insulating film. In the drawings, a p-channel type MOS transistor (referred to as a PMOS transistor) is differentiated from an n-channel type MOS transistor (referred to as a NMOS transistor) by attaching a circle mark symbol to the gate of the p-channel type MOS transistor. Although coupling of a substrate potential to the MOS transistors is not illustrated in the drawings, a coupling method of the substrate potential is not limited in particular as long as the MOS transistors normally operate.

Hereinafter, the embodiments of the present invention will be described in detail with reference to the drawings. In all the drawings for explaining the embodiments, the same symbol is attached to the same member, as a principle, and the repeated explanation thereof is omitted.

### First Embodiment

<<Outline and Problem of Voltage Monitoring Circuit (Comparative Example)>>

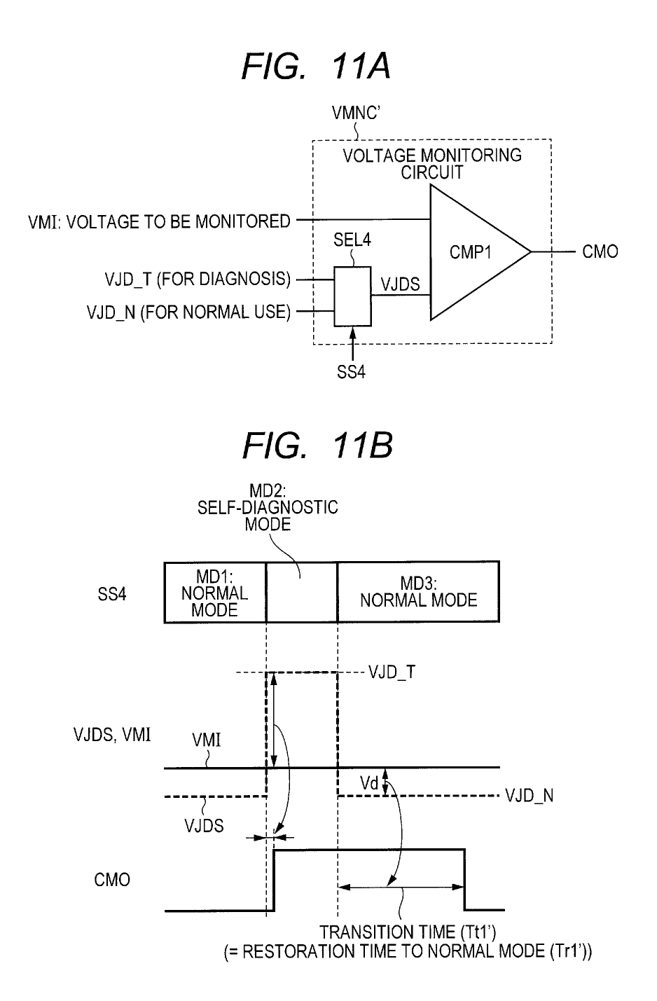

First, a voltage monitoring circuit of a comparative example will be described before describing a voltage monitoring circuit of a first embodiment. FIG. 11A is a schematic diagram showing a configuration example of the voltage monitoring circuit studied as the comparative example of the present invention. In addition to a voltage to be monitored VMI, a determination threshold voltage VJD_N for normal use and a determination threshold voltage VJD_T for self-diagnosis are inputted to a voltage monitoring circuit VMNC′ shown in FIG. 11A. The determination threshold voltage VJD_N for normal use is a voltage for detecting a presence or absence of a specification violation such as an upper limit specification violation and a lower limit specification violation of the voltage to be monitored VMI during a normal operation. On the other hand, the determination threshold voltage VJD_T for self-diagnosis is a voltage for causing the voltage monitoring circuit VMNC′ to forcibly output a detection result indicating that there is a specification violation.

The voltage monitoring circuit VMNC′ includes a selection circuit SEL4 and a comparison circuit CMP1. The selection circuit SEL4 selects either one of the determination threshold voltage VJD_T for self-diagnosis and the determination threshold voltage VJD_N for normal use based on a selection signal SS4. The comparison circuit CMP1 detects a presence or absence of a specification violation of the voltage to be monitored VMI by comparing a selected voltage VJDS selected by the selection circuit SEL4 and the voltage to be monitored VMI and outputs an output signal CMO representing a result of the detection.

FIG. 11B is a schematic diagram showing an operation example of a self-diagnosis in the voltage monitoring circuit of FIG. 11A. As shown in FIG. 11B, when a self-diagnosis is performed, the voltage monitoring circuit VMNC′ sequentially transits from a normal mode MD1 which is an initial state to a self-diagnostic mode MD2 and then to a normal mode MD3 when the selection signal SS4 is controlled by a self-diagnosis control circuit not shown in the drawings. Accordingly, the selection circuit SEL4 defines the determination threshold voltage VJD_N for normal use as an initial state and sequentially selects the determination threshold voltage VJD_T for self-diagnosis, and the determination threshold voltage VJD_N for normal use.

The determination threshold voltage VJD_T for self-diagnosis is a voltage having a polarity reverse to that of the determination threshold voltage VJD_N for normal use with reference to the voltage to be monitored VMI. In the example of FIG. 11B, the voltage monitoring circuit VMNC′ detects whether or not the voltage to be monitored VMI falls below the determination threshold voltage VJD_N for normal use during a normal use (normal mode). In this case, with reference to the voltage to be monitored VMI, the determination threshold voltage VJD_N for normal use is set on the negative side and the determination threshold voltage VJD_T for self-diagnosis is set on the positive side.

Further, the determination threshold voltage VJD_T for self-diagnosis is set to a value where a sufficient potential difference is generated with reference to the voltage to be monitored VMI. As a result, when the transition to the self-diagnostic mode MD2 is performed, the comparison circuit CMP1 causes the output signal CMO to quickly transition from ‘L’ level to ‘H’ level. The ‘H’ level of the output signal CMO represents a detection result indicating that there is a specification violation (lower limit specification violation) and the ‘L’ level represents a detection result indicating that there is no specification violation.

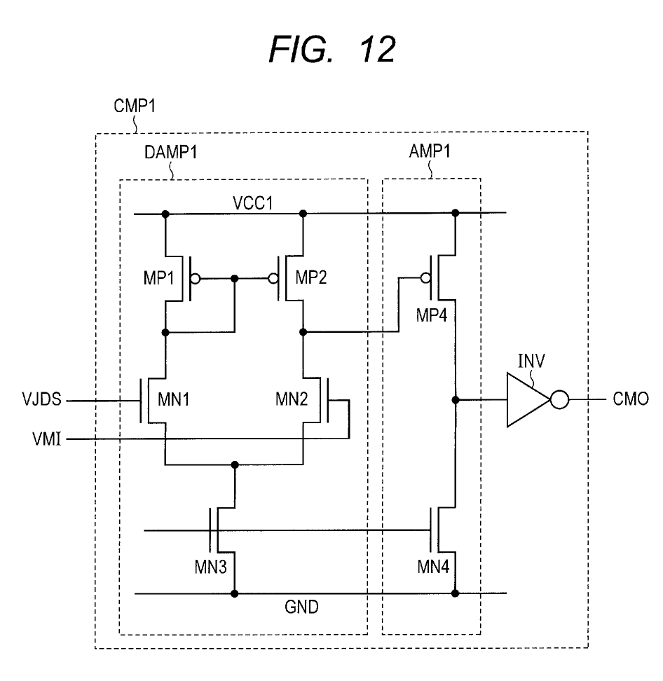

Thereafter, when the voltage monitoring circuit VMNC′ transits from the self-diagnostic mode MD2 to the normal mode MD3, the comparison circuit CMP1 causes the output signal CMO to transition from ‘H’ level to ‘L’ level. However, as shown in FIG. 11B, when a potential difference Vd between the voltage to be monitored VMI and the determination threshold voltage VJD_N for normal use is small, as described in FIG. 12, there is a risk that a transition time Tt1′ of the output signal CMO from the ‘H’ level to the ‘L’ level becomes long. When the transition time Tt1′ becomes long, an effective restoration time Tr1′ to the normal mode MD3 also becomes long by being restricted by the transition time Tt1′.

FIG. 12 is a circuit diagram showing a configuration example of the comparison circuit in the voltage monitoring circuit of FIG. 11A. The comparison circuit CMP1 shown in FIG. 12 includes a differential amplifier circuit DAMP1, a grounded source amplifier circuit AMP1 that is cascade-coupled to the comparison circuit CMP1 as a post-stage circuit of the comparison circuit CMP1, and an inverter circuit INV that outputs the output signal CMO by inverting an output of the grounded source amplifier circuit AMP1. The differential amplifier circuit DAMP1 includes NMOS transistors MN1 and MN2 which are differential pair transistors, a pair of PMOS transistors MP1 and MP2 which are a load current source for differential amplification, and a NMOS transistor MN3 which is a tail current source. The PMOS transistors MP1 and MP2 are coupled between a power supply voltage VCC1 and the NMOS transistors MN1 and MN2, respectively. The NMOS transistor MN3 is coupled between a common source node of the NMOS transistors MN1 and MN2 and a ground power supply voltage GND.

The grounded source amplifier circuit AMP1 includes a PMOS transistor MP4 whose source is coupled to the power supply voltage VCC1 and which is driven by an output of the differential amplifier circuit DAMP1 and an NMOS transistor MN4 whose source is coupled to the ground power supply voltage GND and which functions as a load current source for amplification. In the differential amplifier circuit DAMP1, the NMOS transistor MN′ is driven by the selected voltage VJDS and the NMOS transistor MN2 is driven by the voltage to be monitored VMI.

Here, when a mutual conductance between the NMOS transistors MN1 and MN2 is “gm” and a differential input voltage to the NMOS transistors MN1 and MN2 is the potential difference Vd shown in FIG. 11B, an output current “I” of the differential amplifier circuit DAMP1 is “gm×Vd”. The gate of the PMOS transistor MP4 of the grounded source amplifier circuit AMP1 is charged and discharged by the output current “I”. When an input voltage amplitude of the gate of the PMOS transistor MP4 reaches a predetermined amplitude by the charge and discharge, the grounded source amplifier circuit AMP1 can invert a logic of the inverter circuit INV.

On this occasion, when a gate capacity of the PMOS transistor MP4 is “Cg”, the input voltage amplitude of the gate of the PMOS transistor MP4 required to invert the logic of the inverter circuit INV is “ΔVg”, and a charge/discharge time of the gate capacity of the PMOS transistor MP4 is “T”, a relationship of equation (1) is established. Further, the equation (2) is established by modifying the equation (1). As known from the equation (2), the smaller the potential difference Vd, the longer the charge/discharge time required to invert the logic of the inverter circuit INV (that is, the transition time Tt1′ of FIG. 11B).

I×T=Cg×ΔVg (1)

T=(Cg×ΔVg)/I=(Cg×ΔVg)/(gm×Vd) (2)

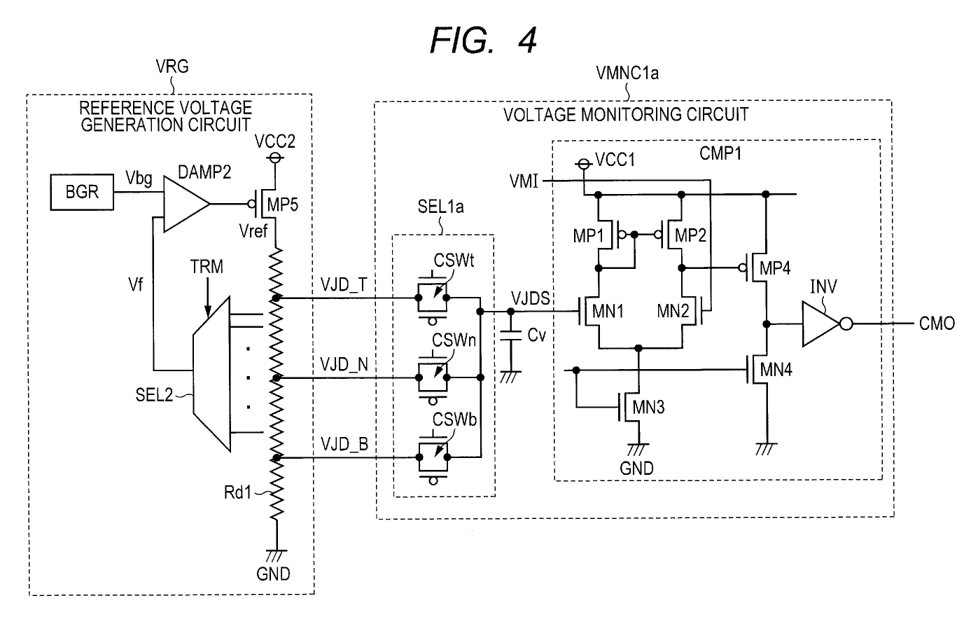

Under such circumstances, the potential difference Vd required as specifications is becoming smaller and smaller by being influenced by the lowering of voltage of semiconductor devices as described above. Further, the determination threshold voltage VJD_N for normal use is generated by, for example, a reference voltage generation circuit (see FIG. 4) including a bandgap reference circuit and the like and is a voltage having low dependency on the temperature and the power supply voltage. However, the determination threshold voltage VJD_N for normal use may vary for each semiconductor device (semiconductor chip) according to process variation. Considering such variation, there is a risk that the actual potential difference Vd further reduces.

The smaller the potential difference Vd, the longer the effective restoration time Tr1′ to the normal mode MD3 shown in FIG. 11B, and the self-diagnosis cannot be completed until the normal mode MD3 is effectively restored, so that the time required for the self-diagnosis becomes long. For example, when the potential difference Vd is about 50 mV, the restoration time Tr1′ is required to be tens of microseconds or less. However, the potential difference Vd may be several milliseconds in some cases. If the self-diagnosis is performed when the semiconductor device is started, prolongation of the time of self-diagnosis causes an increase of start-up time of the semiconductor device.

### <<Outline of Voltage Monitoring Circuit (First Embodiment)>>

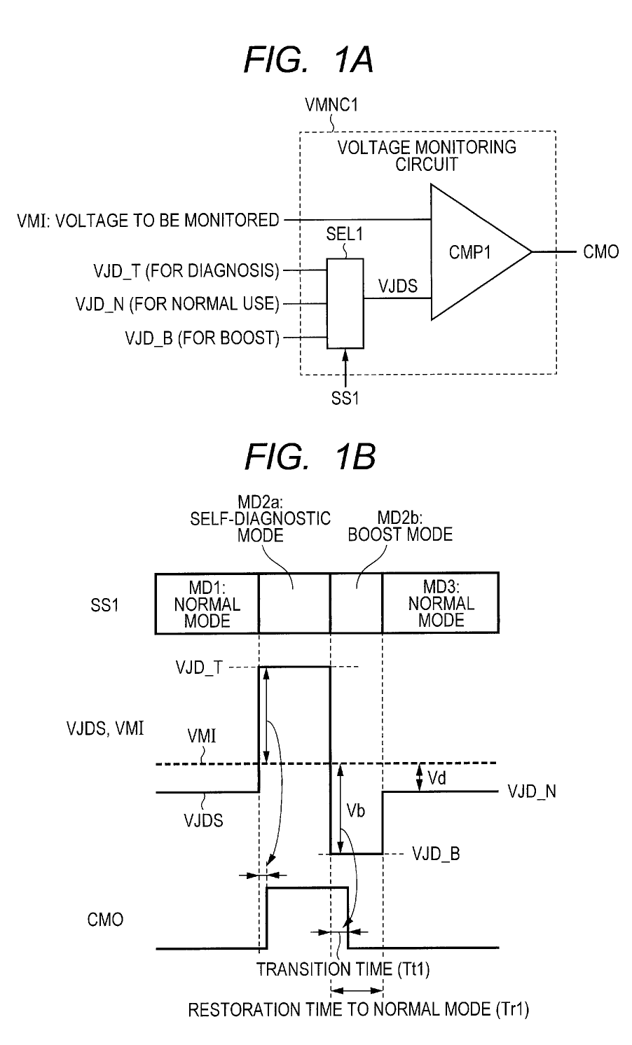

FIG. 1A is a schematic diagram showing a configuration example of a voltage monitoring circuit according to the first embodiment of the present invention. As a method for reducing the transition time Tt1′ of FIG. 11B, for example, (A) a method of increasing an operating current of the comparison circuit CMP1 and (B) a method of reducing a transistor size of the PMOS transistor MP4 of FIG. 12 are considered. However, in the method of (A), a consumption current increases and this causes increase of consumption current of the entire semiconductor chip. The method of (B) causes increase of relative characteristics variation between semiconductor chips in the PMOS transistor MP4, so that there is a risk that this causes a variation of determination threshold voltage between the semiconductor chips.

Therefore, it is useful to use a method of FIG. 1A as a method that does not cause the problems of (A) and (B). The voltage monitoring circuit VMNC1 shown in FIG. 1A is different from the configuration example of FIG. 11A in that a determination threshold voltage VJD_B for boost is further inputted into the voltage monitoring circuit VMNC1. The determination threshold voltage VJD_B for boost is a voltage for temporarily increasing an input potential difference to the comparison circuit CMP1 when the mode transits from the self-diagnostic mode to the normal mode.

The voltage monitoring circuit VMNC1 includes a selection circuit SEL1 and a comparison circuit CMP1. The selection circuit SEL1 selects any one of the determination threshold voltage VJD_T for self-diagnosis, the determination threshold voltage VJD_N for normal use, and the determination threshold voltage VJD_B for boost based on a selection signal SS1. The comparison circuit CMP1 is formed by, for example, a circuit shown in FIG. 12. The comparison circuit CMP1 detects a presence or absence of a specification violation of the voltage to be monitored VMI by comparing a selected voltage VJDS selected by the selection circuit SEL1 and the voltage to be monitored VMI and outputs an output signal CMO representing a result of the detection.

FIG. 1B is a schematic diagram showing an operation example of a self-diagnosis in the voltage monitoring circuit of FIG. 1A. As shown in FIG. 1B, when a self-diagnosis is performed, the voltage monitoring circuit VMNC1 sequentially transits from a normal mode MD1, which is an initial state, to a self-diagnostic mode MD2a, to a boost mode MD2b, and then to a normal mode MD3 when the selection signal SS1 is controlled by a self-diagnosis control circuit not shown in the drawings. Accordingly, the selection circuit SEL1 sequentially defines the determination threshold voltage VJD_N for normal use an initial state and sequentially selects the determination threshold voltage VJD_T for self-diagnosis, the determination threshold voltage VJD_B for boost, and the determination threshold voltage VJD_N for normal use.

In the same manner as in FIG. 11B, the determination threshold voltage VJD_T for self-diagnosis is a voltage having a polarity reverse to that of the determination threshold voltage VJD_N for normal use with reference to the voltage to be monitored VMI. On the other hand, the determination threshold voltage VJD_B for boost is a voltage having the same polarity as that of the determination threshold voltage VJD_N for normal use with reference to the voltage to be monitored VMI and is a voltage having a potential difference larger than that of the determination threshold voltage VJD_N for normal use.

In the example of FIG. 1B, the voltage monitoring circuit VMNC1 detects whether or not the voltage to be monitored VMI falls below the determination threshold voltage VJD_N for normal use (that is, detects a presence or absence of a lower limit specification violation) during a normal use (normal mode). In this case, with reference to the voltage to be monitored VMI, the determination threshold voltage VJD_N for normal use and the determination threshold voltage VJD_B for boost are set on the negative side and the determination threshold voltage VJD_T for self-diagnosis is set on the positive side. Further, with reference to the voltage to be monitored VMI, a potential difference Vb of the determination threshold voltage VJD_B for boost is greater than a potential difference Vd of the determination threshold voltage VJD_N for normal use.

In the same manner as in FIG. 11B, the determination threshold voltage VJD_T for self-diagnosis is set to a value where a sufficient potential difference is generated with reference to the voltage to be monitored VMI. As a result, when the transition to the self-diagnostic mode MD2a is performed, the comparison circuit CMP1 causes the output signal CMO to quickly transition from ‘L’ level to ‘H’ level. Thereafter, the voltage monitoring circuit VMNC1 transits from the self-diagnostic mode MD2a to the boost mode MD2b. In the boost mode MD2b, a sufficient potential difference Vb is inputted into the comparison circuit CMP1, so that the comparison circuit CMP1 causes the output signal CMO to quickly transition from ‘H’ level to ‘L’ level according to the transition to the boost mode MD2b. Thereafter, when the transition from the boost mode MD2b to the normal mode MD3 is performed, the selected voltage VJDS inputted into the comparison circuit CMP1 returns from the determination threshold voltage VJD_B for boost to the determination threshold voltage VJD_N for normal use.

When the configuration and operation as described above are used, as shown in FIG. 1B, the restoration time Tr1 to the normal mode is not restricted by the transition time Tt1 of the output signal CMO in a manner different from that in FIG. 11B. As a result, the voltage monitoring circuit VMNC1 can effectively return to the normal mode MD3 at a time point when the voltage monitoring circuit VMNC1 transits from the boost mode MD2b to the normal mode MD3 according to the selection signal SS1. Thereby, it is possible to reduce the time required for the self-diagnosis, and accordingly, it is possible to reduce the start-up time of the semiconductor device.

The greater the potential difference Vb shown in FIG. 1B, the smaller the transition time Tt1 can be, so that by reducing the time of the boost mode MD2b accordingly, it is possible to reduce the effective restoration time Tr1 to the normal mode MD3. However, when the potential difference Vb is too large, in some cases, there is a risk that an overshoot or the like occurs when the selected voltage VJDS returns from the determination threshold voltage VJD_B for boost to the determination threshold voltage VJD_N for normal use, so that the potential difference Vb is determined by trade-off of these conditions.

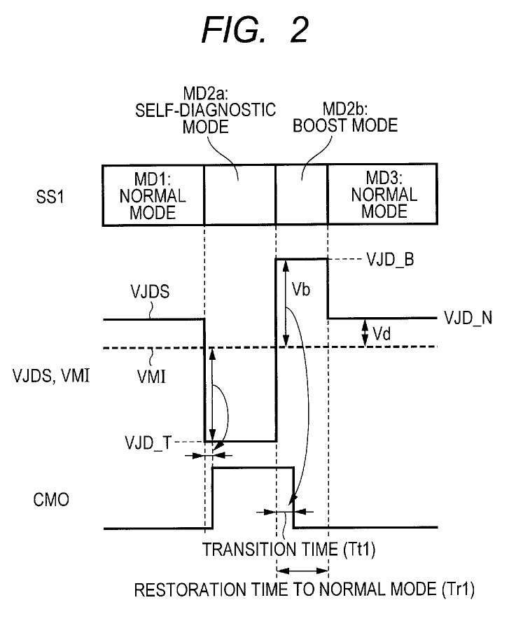

FIG. 2 is a schematic diagram showing an operation example different from that in FIG. 1B. In FIG. 2, in the same manner as in FIG. 11B, the determination threshold voltage VJD_T for self-diagnosis is a voltage having a polarity reverse to that of the determination threshold voltage VJD_N for normal use with reference to the voltage to be monitored VMI. Further, in the same manner as in FIG. 1B, the determination threshold voltage VJD_B for boost is a voltage having the same polarity as that of the determination threshold voltage VJD_N for normal use with reference to the voltage to be monitored VMI and is a voltage having a potential difference larger than that of the determination threshold voltage VJD_N for normal use.

However, in the example of FIG. 2, different from the case of FIG. 1B, the voltage monitoring circuit VMNC1 detects whether or not the voltage to be monitored VMI rises above the determination threshold voltage VJD_N for normal use (that is, detects a presence or absence of an upper limit specification violation) during a normal use (normal mode). In this case, with reference to the voltage to be monitored VMI, the determination threshold voltage VJD_N for normal use and the determination threshold voltage VJD_B for boost are set on the positive side and the determination threshold voltage VJD_T for self-diagnosis is set on the negative side.

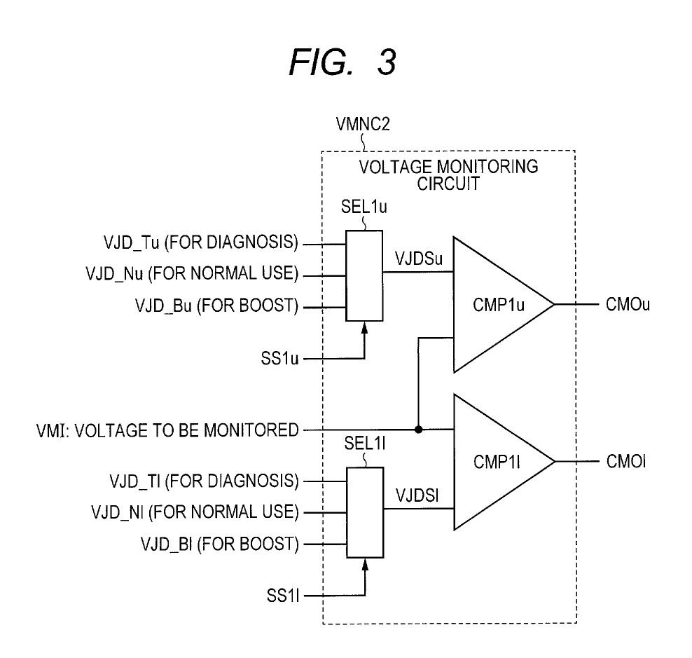

FIG. 3 is a schematic diagram showing a configuration example obtained by expanding the voltage monitoring circuit of FIG. 1A. The voltage monitoring circuit VMNC2 shown in FIG. 3 includes two voltage monitoring circuits shown in FIG. 1A. One voltage monitoring circuit includes a selection circuit SEL1u and a comparison circuit CMP1u and the other voltage monitoring circuit includes a selection circuit SEL1l and a comparison circuit CMP1l. The selection circuits SEL1u and SEL1l perform selection operations based on selection signals SSlu and SS1l and output selected voltages VJDSu and VJDSl, respectively.

A determination threshold voltage VJD_Nl for normal use inputted into the selection circuit SEL1l has a potential lower than that of the voltage to be monitored VMI, and a determination threshold voltage VJD_Nu for normal use inputted into the selection circuit SEL1u has a potential higher than that of the voltage to be monitored VMI. Thereby, the selection circuit SEL1l and the comparison circuit CMP1l perform an operation as shown in FIG. 1B based on the determination threshold voltage VJD_Nl for normal use and output an output signal CMOl representing a detection result indicating a lower limit specification violation. On the other hand, the selection circuit SEL1u and the comparison circuit CMP1u perform an operation as shown in FIG. 2 based on the determination threshold voltage VJD_Nu for normal use and output an output signal CMOu representing a detection result indicating an upper limit specification violation.

### <<Details Around Voltage Monitoring Circuit (First Embodiment)>>

FIG. 4 is a circuit diagram showing a detailed configuration example around the voltage monitoring circuit of FIG. 1A. Here, the voltage monitoring circuit that performs the operation of FIG. 1B is used as an example. In FIG. 4, a reference voltage generation circuit VRG includes a bandgap reference circuit BGR, a differential amplifier circuit DAMP2, a PMOS transistor MP5, a resistance element Rd1, and a selection circuit SEL2 and generates determination threshold voltages for self-diagnosis, normal use, and boost (VJD_T, VJD_N, and VJD_B).

As widely known, the bandgap reference circuit BGR generates a bandgap voltage Vbg (for example, about 1.2 V) independent of temperature and power supply voltage by using characteristics of pn junction. The differential amplifier circuit DAMP2 drives the PMOS transistor MP5 so that the bandgap voltage Vbg matches a feedback voltage Vf from the selection circuit SEL2. The source of the PMOS transistor MP5 is coupled to a power supply voltage VCC2 and the PMOS transistor MP5 is driven by the differential amplifier circuit DAMP2, and thereby the PMOS transistor MP5 generates a reference voltage Vref at its drain. The resistance element Rd1 appropriately resistance-divides the reference voltage Vref.

The selection circuit SEL2 appropriately selects a resistance voltage dividing node (tap) of the resistance element Rd1 based on a trimming signal TRM and outputs a voltage of the selected tap as the feedback voltage Vf. A value of the trimming signal TRM is determined for each semiconductor chip in a manufacturing stage of a semiconductor device (semiconductor chip), and the value is determined so that the reference voltages Vref are the same voltage value even when process variation occurs between semiconductor chips. The resistance element Rd1 appropriately resistance-divides the reference voltage Vref to generate the determination threshold voltages for self-diagnosis, normal use, and boost (VJD_T, VJD_N, and VJD_B).

A voltage monitoring circuit VMNC1a includes a selection circuit SEL1a, a capacitor Cv, and a comparison circuit CMP1 as shown in FIG. 12. The capacitor Cv holds the selected voltage VJDS which is the gate voltage of the NMOS transistor MN1 of the comparison circuit CMP1. Here, the selection circuit SEL1a includes CMOS switches CSWt, CSWn, and CSWb. The CMOS switches CSWt, CSWn, and CSWb determine whether or not to transmit the determination threshold voltages for self-diagnosis, normal use, and boost (VJD_T, VJD_N, and VJD_B), respectively, to the capacitor Cv.

Although the gates of NMOS transistor and PMOS transistor included in the CMOS switches CSWt, CSWn, and CSWb are not shown in the drawings, the gates are controlled by the selection signal SS1 shown in FIG. 1A. For example, when the determination threshold voltage VJD_N for normal use is transmitted to the capacitor Cv (in other words, the determination threshold voltage VJD_N for normal use is selected as the selected voltage VJDS), the CMOS switch CSWn is controlled to be turned on and the CMOS switches CSWt and CSWb are controlled to be turned off.

### <<Outline of Semiconductor Device>>

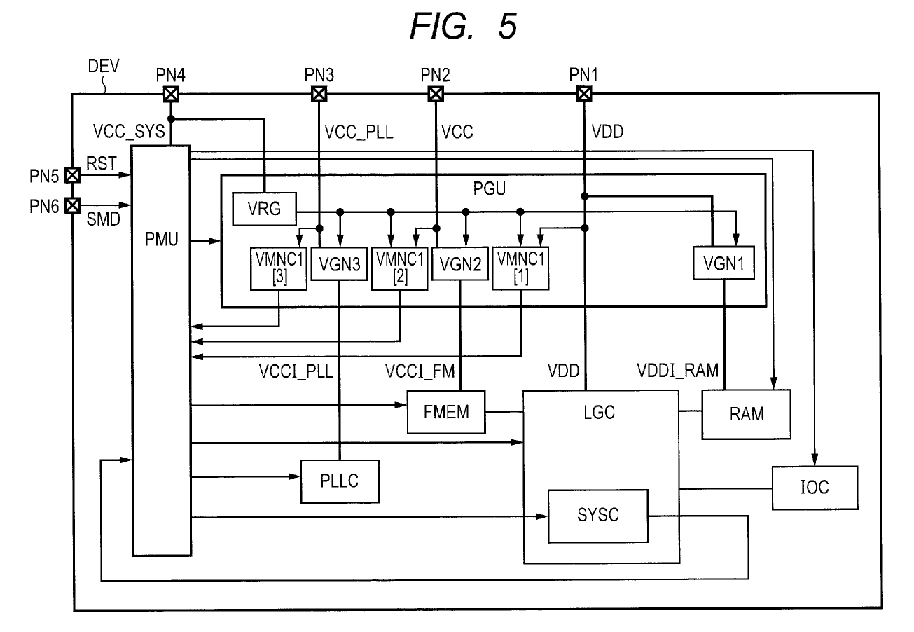

FIG. 5 is a schematic diagram showing a configuration example of a semiconductor device according to the first embodiment of the present invention. The semiconductor device DEV shown in FIG. 5 is composed of one semiconductor chip and is an in-vehicle microcontroller chip or the like although not limited in particular. The semiconductor chip DEV includes a plurality of external terminals including external terminals PN1 to PN6. Power supply voltages VDD, VCC, VCC_PLL, and VCC_SYS are supplied to the external terminals PN1, PN2, PN3, and PN4, respectively. A reset signal RST is inputted into the external terminal PN5, and a system mode signal SMD is inputted into the external terminal PN6.

The semiconductor device DEV includes a power supply management unit PMU, a power supply generation unit PGU, a PLL (Phase Locked Loop) circuit PLLC, a flash memory FMEM, a logic circuit LGC, a non-volatile memory RAM, and an IO circuit IOC. The power supply management unit PMU operates with a power supply voltage VCC_SYS and manages various power supplies used in the semiconductor device DEV. For example, the power supply management unit PMU performs control of power-on reset according to the reset signal RST, power saving control of the semiconductor device DEV according to the system mode signal SMD (for example, control of activating/deactivating various circuit blocks), and the like.

As shown in FIG. 4, the power supply generation unit PGU includes the reference voltage generation circuit VRG and a plurality of voltage monitoring circuits VMNC1 [1] to VMNC1 [3] and further includes power supply generation circuits (regulator circuits) VGN1 to VGN3. The reference voltage generation circuit VRG operates with the power supply voltage VCC_SYS. The power supply generation circuits VGN1 to VGN3 receive a predetermined reference voltage from the reference voltage generation circuit VRG and power supply voltages from external terminals and generate various internal power supply voltages. Here, the power supply generation circuit VGN1 receives the power supply voltage VDD and generates an internal power supply voltage for the non-volatile memory RAM. The power supply generation circuit VGN2 receives the power supply voltage VCC and generates an internal power supply voltage for the flash memory FMEM. The power supply generation circuit VGN3 receives the power supply voltage VCC_PLL and generates an internal power supply voltage for the PLL circuit PLLC.

The voltage monitoring circuit VMNC1 [1] monitors the power supply voltage VDD, the voltage monitoring circuit VMNC1 [2] monitors the power supply voltage VCC, and the voltage monitoring circuit VMNC1 [3] monitors the power supply voltage VCC_PLL. The PLL circuit PLLC generates various clock signals required in the semiconductor device DEV. The logic circuit LGC operates with the power supply voltage VDD. The logic circuit LGC includes an MPU (Micro Processing Unit) that performs predetermined program processing by using data of the flash memory FMEM and the non-volatile memory RAM and a system control circuit SYSC that manages the state and the like of the entire system. The non-volatile memory RAM is a SRAM (Static Random Access Memory), a DRAM (Dynamic Random Access Memory), or the like. The IO circuit IOC plays a role of an input/output interface to the outside of the semiconductor device DEV.

In such a configuration, for example, the power supply management unit PMU is equipped with a self-diagnosis control circuit. When performing self-diagnosis, the power supply management unit PMU (the self-diagnosis control circuit) controls each selection circuit (for example, SEL1a of FIG. 4) in the voltage monitoring circuits VMNC1 [1] to VMNC1 [3] and thereby causes the selection circuit to select each determination threshold voltage in the order shown in FIG. 1B by using the determination threshold voltage VJD_N for normal use as in initial state. Then, the power supply management unit PMU receives detection results (the output signal CMO of FIG. 4) of the voltage monitoring circuits VMNC1 [1] to VMNC1 [3].

Although not particularly limited, specifically, the power supply management unit PMU first causes the voltage monitoring circuit VMNC1 [1] to detect that there is a specification violation by controlling the selection signal SS1 of the voltage monitoring circuits VMNC1 [1] in the manner as shown in FIG. 1B after the power-on reset according to the reset signal RST. The power supply management unit PMU receives a detection result indicating that there is the specification violation and notifies the system control circuit SYSC in the logic circuit LGC of the detection result. The system control circuit SYSC receives the notification and performs predetermined error processing, and thereafter transmits completion notification to the power supply management unit PMU. The power supply management unit PMU receives the completion notification and performs the same self-diagnosis on, for example, the next voltage monitoring circuit VMNC1 [2].

Here, for example, the power supply voltage VDD is about 1.25 V, the power supply voltage VCC_SYS is about 3.0 V, and the power supply voltages VCC and VCC_PLL are about 3.0 V to 5.0 V. In such a case, in particular, it is required to manage the power supply voltage VDD within a small range, so that it is desirable to apply a method of FIG. 1A to at least the voltage monitoring circuit VMNC1 [1].

For example, the power supply voltage VDD is managed within a range of 1.25 V±0.05 V, and the determination threshold voltage VJD_N for normal use used to detect a lower limit specification violation is set to 1.2 V-ΔV (ΔV is a variation margin) or the like. In this case, the determination threshold voltage VJD_T for self-diagnosis is set to, for example, about 1.5 V, and the determination threshold voltage VJD_B for boost is set to, for example, about 1.0 V. Regarding the other voltage monitoring circuits VMNC1 [2] and VMNC1 [3], a method of FIG. 11A can be applied instead of the method of FIG. 1A depending on a value of the potential difference Vd.

### <<Main Effects of First Embodiment>>

As described above, when the voltage monitoring circuit and the semiconductor device of the first embodiment are used, typically, it is possible to reduce the time required for the self-diagnosis, and accordingly, it is possible to reduce the start-up time of the semiconductor device DEV. Further, as described in FIG. 1A, it is possible to obtain such effects without increasing the power consumption while maintaining a sufficient monitoring accuracy.

### Second Embodiment

### <<Problem of Voltage Monitoring Circuit (Premise)>>

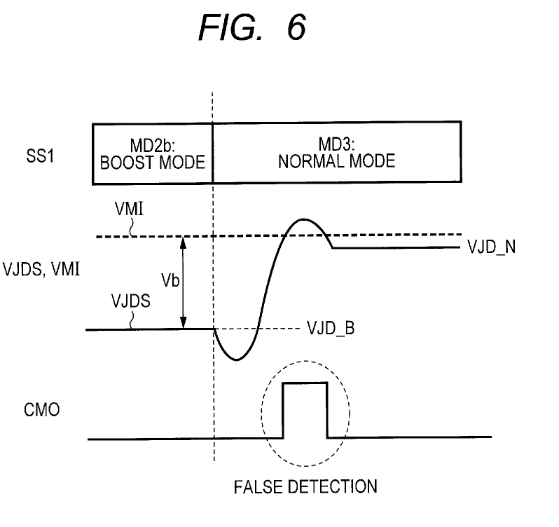

FIG. 6 is a schematic diagram showing an example of a problem that may occur when using the voltage monitoring circuit of FIG. 4. FIG. 6 schematically shows a situation when the boost mode MD2b transits to the normal mode MD3 in FIG. 1B. As shown in FIG. 6, when the selected voltage VJDS is switched from the determination threshold voltage VJD_B for boost to the determination threshold voltage VJD_N for normal use, noise such as overshoot and undershoot may occur in the selected voltage VJDS due to movement of charges of the capacitor Cv. As a result, as shown in FIG. 6, there is a risk that false detection occurs in the comparison circuit CMP1.

The smaller the potential difference Vb between the voltage to be monitored VMI and the determination threshold voltage VJD_B for boost, the more suppressed the noise described above. However, by doing so, the transition time Tt1 (the restoration time Tr1) becomes long as described in FIG. 1B. The noise is superimposed on the reference voltage Vref through the selection circuit SEL1a and the resistance element Rd1 of FIG. 4. In this case, as shown in FIG. 5, the noise may go around a plurality of power supply generation circuits VGN1 to VGN3 that share the reference voltage generation circuit VRG and a plurality of voltage monitoring circuits VMNC1 [1] to VMNC1 [3] and adversely affect these circuits. Specifically, for example, when the plurality of voltage monitoring circuits VMNC1 [1] to VMNC1 [3] perform self-diagnosis in parallel, there is a risk that false detection occurs in these circuits, and further there is a risk that a malfunction occurs in circuits to which power is supplied from the power supply generation circuits VGN1 to VGN3 and which have been started.

### <<Details Around Voltage Monitoring Circuit (Second Embodiment)>>

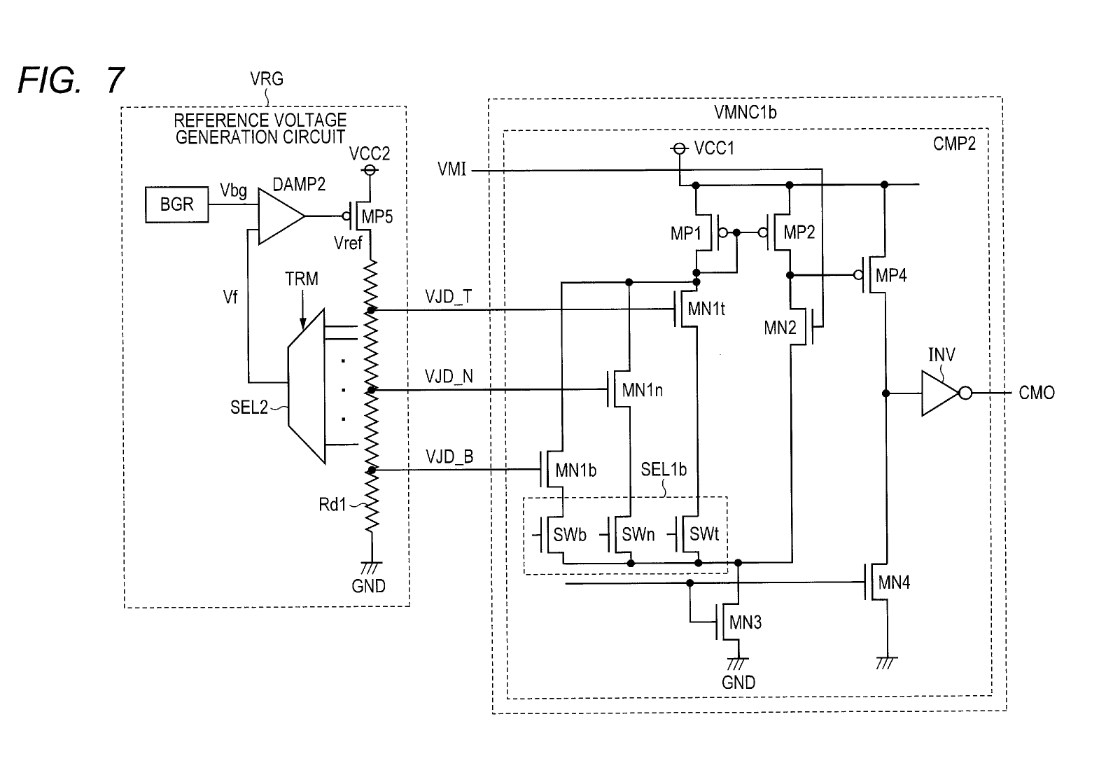

FIG. 7 is a circuit diagram showing a detailed configuration example around a voltage monitoring circuit according to a second embodiment of the present invention. A voltage monitoring circuit VMNC1b shown in FIG. 7 is different from the voltage monitoring circuit VMNC1a of FIG. 4 in the following two points. The first different point is that a comparison circuit CMP2 of FIG. 7 includes three NMOS transistors MN1t, MN1n, and MN1b instead of the NMOS transistor MN1 in the comparison circuit CMP1 of FIG. 4. Drain nodes of the NMOS transistors MN1t, MN1n, and MN1b are coupled in common. The NMOS transistor MN1t is driven by the determination threshold voltage VJD_T for self-diagnosis, the NMOS transistor MN1n is driven by the determination threshold voltage VJD_N for normal use, and the NMOS transistor MN1b is driven by the determination threshold voltage VJD_B for boost.

The second different point is that the comparison circuit CMP2 of FIG. 7 includes a selection circuit SEL1b in the comparison circuit CMP2 instead of the selection circuit SEL1a of FIG. 4. The selection circuit SEL1b includes three switches (here, three NMOS transistors) SWt, SWn, and SWb. One ends of the three switches SWt, SWn, and SWb are coupled in common, and the other ends are coupled to the three NMOS transistors MN1t, MN1n, and MN1b, respectively. In other words, the three switches SWt, SWn, and SWb are inserted into current paths of the three NMOS transistors MN1t, MN1n, and MN1b, respectively. When the selection circuit SEL1b selects, for example, the determination threshold voltage VJD_N for normal use, the selection circuit SEL1b controls the switch SWn to turn on and controls the remaining switches SWt and SWb to turn off.

When the voltage monitoring circuit VMNC1b as shown in FIG. 7 is used, the movement of charges as described in FIG. 6 does not occur, so that noise can be reduced and it is possible to prevent false detection in the voltage monitoring circuit. Further, noise does not affect the reference voltage Vref, so that it is possible to prevent false detection in each voltage monitoring circuit and prevent malfunction of each circuit. As a result, the potential difference Vb between the voltage to be monitored VMI and the determination threshold voltage VJD_B for boost may be further increased, and accordingly the time required for the self-diagnosis may be reduced.

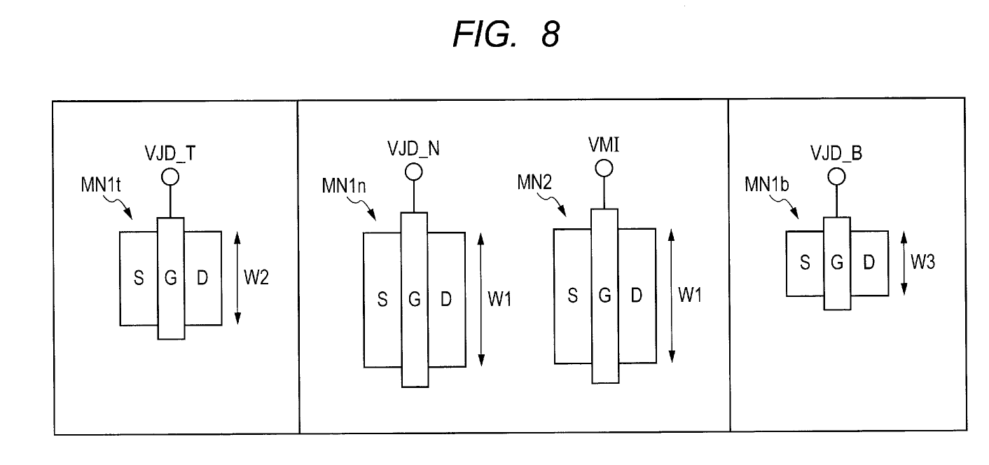

FIG. 8 is a pattern diagram showing an example of a size relationship of main transistors in the voltage monitoring circuit of FIG. 7. In the comparison circuit CMP2 of FIG. 7, the NMOS transistor MN1 of FIG. 4 is divided into three transistors, so that there is concern over increase in circuit area as compared with the case of FIG. 4. Therefore, it is useful to determine the size of each transistor as shown in FIG. 8. FIG. 8 shows a simple layout configuration of each MOS transistor. In this example, although not necessarily limited, the size of each MOS transistor is determined by the gate width while the gate length is constant.

In FIG. 8, the NMOS transistor MN1n driven by the determination threshold voltage VJD_N for normal use and the NMOS transistor MN2 that forms differential pair transistors with the NMOS transistor MN1n are set to the same size (gate width W1), and set to a relatively large size in order to suppress influence of process variation (that is, degradation of accuracy of monitored voltage). On the other hand, the NMOS transistor MN1t driven by the determination threshold voltage VJD_T for self-diagnosis and the NMOS transistor MN1b driven by the determination threshold voltage VJD_B for boost are not particularly affected by process variation (that is, accuracy of monitored voltage), so that both of the transistors or at least one of them are set to a size smaller than the NMOS transistor MN1n.

In this example, both of the NMOS transistors MN1t and MN1b are set to a size smaller than the NMOS transistor MN1n. Referring to FIGS. 7 and 8, the NMOS transistor MN1t may have driving capability that can discharge a voltage of drain node to ‘L’ level by the determination threshold voltage VJD_T for self-diagnosis and is set to a size (gate width W2) as small as possible within a range of the driving capability.

While the NMOS transistor MN1t plays a role of discharging a drain voltage of ‘H’ level to ‘L’ level by a strong on state, the NMOS transistor MN1b plays a role of causing the PMOS transistor MP1 to charge a drain voltage of ‘L’ level to ‘H’ level by a weak on state. According to these roles, the NMOS transistor MN1b does not need driving capability in particular as compared with the NMOS transistor MN1t. Therefore, the size (gate width W3) of the NMOS transistor MN1b may be smaller than the size (gate width W2) of the NMOS transistor MN1t.

By the setting of the transistor sizes as described above, it is possible to reduce the circuit area as compared with a case in which, for example, all the NMOS transistors MN1t, MN1n, and MN1b have the same size (gate width W1), so that it is possible to sufficiently suppress overhead of the circuit area as compared with the case of FIG. 4. For example, NMOS transistors that form the switches SWt, SWn, and SWb may be formed with a gate width greater than the gate width W1. However, in view of the roles as described above, it is possible to cause the NMOS transistors that form the switches SWt, SWn, and SWb to have the same size ratio as that in the case of the NMOS transistors MN1t, MN1n, and MN1b.

### <<Main Effects of Second Embodiment>>

As described above, when the voltage monitoring circuit and the semiconductor device of the second embodiment are used, in addition to the various effects described in the first embodiment, it is possible to prevent false detection in the voltage monitoring circuit and malfunction of various circuits. Therefore, the reliability is improved. Further, it is possible to obtain these effects while suppressing the overhead of the circuit area.

### Third Embodiment

### <<Problem of Voltage Monitoring Circuit (Premise)>>

For example, when the reference voltage generation circuit VRG as shown in FIG. 4 is used, it is difficult to increase the power supply voltage VCC2 of the reference voltage generation circuit VRG, so that the value of the maximum reference voltage Vref that can be generated may be limited to, for example, about 2.0 V. For example, such a situation occurs when it is necessary to monitor the power supply voltage VCC2 of the reference voltage generation circuit VRG by using a determination threshold voltage from the reference voltage generation circuit VRG itself. As a result, there is a risk that it is difficult to monitor a voltage when the voltage to be monitored is a high voltage such as 5.0 V.

### <<Outline of Voltage Monitoring Circuit (Third Embodiment)>>

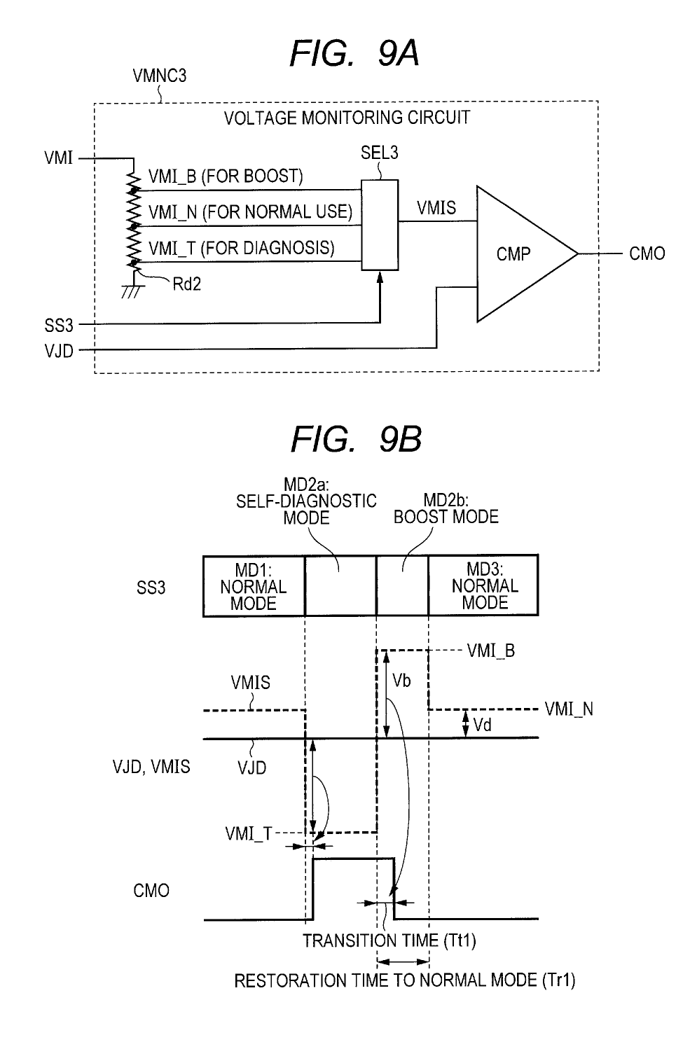

FIG. 9A is a schematic diagram showing a configuration example of a voltage monitoring circuit according to a third embodiment of the present invention. A voltage monitoring circuit VMNC3 shown in FIG. 9A uses a method which is different from the method of FIG. 1A and which causes the voltage to be monitored VMI instead of the determination threshold voltage VJD to be lowered and transitioned. The voltage monitoring circuit VMNC3 includes a resistance element Rd2, a selection circuit SEL3, and a comparison circuit CMP. The resistance element Rd2 resistance-divides the voltage to be monitored VMI to generate a voltage to be monitored VMI_B for boost, a voltage to be monitored VMI_N for normal use, and a voltage to be monitored VMI_T for self-diagnosis. In this case, it is possible to sufficiently suppress power consumption at the voltage to be monitored VMI (for example, the power supply voltage) by sufficiently increasing the resistance value of the resistance element Rd2.

The selection circuit SEL3 selects any one of the voltage to be monitored VMI_B for boost, the voltage to be monitored VMI_N for normal use, and the voltage to be monitored VMI_T for self-diagnosis. The comparison circuit CMP detects a presence or absence of a specification violation by comparing a selected voltage VMIS selected by the selection circuit SEL3 and the determination threshold voltage VJD and outputs an output signal CMO representing a result of the detection.

FIG. 9B is a schematic diagram showing an operation example of a self-diagnosis in the voltage monitoring circuit of FIG. 9A. As shown in FIG. 9B, when a self-diagnosis is performed, the voltage monitoring circuit VMNC3 sequentially transits from a normal mode MD1, which is an initial state, to a self-diagnostic mode MD2a, to a boost mode MD2b, and then to a normal mode MD3 when a selection signal SS3 is controlled by a self-diagnosis control circuit not shown in the drawings. Accordingly, the selection circuit SEL3 defines the voltage to be monitored VMI_N for normal use as an initial state and sequentially selects the voltage to be monitored VMI_T for self-diagnosis, the voltage to be monitored VMI_B for boost, and the voltage to be monitored VMI_N for normal use.

The voltage to be monitored VMI_T for self-diagnosis is a voltage having a polarity reverse to that of the voltage to be monitored VMI_N for normal use with reference to the determination threshold voltage VJD. The voltage to be monitored VMI_B for boost is a voltage having the same polarity as that of the voltage to be monitored VMI_N for normal use with reference to the determination threshold voltage VJD and is a voltage having a potential difference larger than that of the voltage to be monitored VMI_N for normal use.

In the example of FIG. 9B, in the same manner as in FIG. 1B, the voltage monitoring circuit VMNC3 detects whether or not the voltage to be monitored VMI (that is, the voltage to be monitored VMI_N for normal use) falls below the determination threshold voltage VJD (that is, detects a presence or absence of a lower limit specification violation) during a normal use (normal mode). In this case, with reference to the determination threshold voltage VJD, the voltage to be monitored VMI_N for normal use and the voltage to be monitored VMI_B for boost are set on the positive side and the voltage to be monitored VMI_T for self-diagnosis is set on the negative side. Further, with reference to the determination threshold voltage VJD, a potential difference Vb of the voltage to be monitored VMI_B for boost is greater than a potential difference Vd of the voltage to be monitored VMI_N for normal use.

### <<Details of Voltage Monitoring Circuit (Third Embodiment)>>

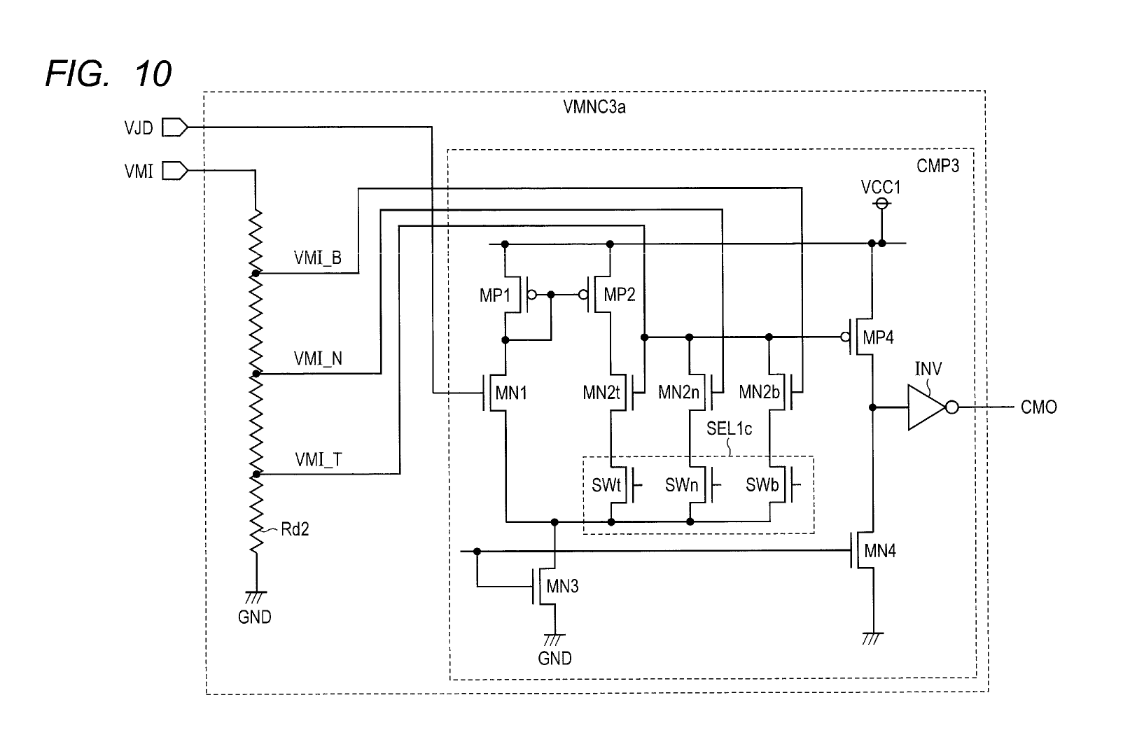

For example, when the same configuration as that of the selection circuit SEL1a and the comparison circuit CMP1 shown in FIG. 4 is applied to the selection circuit SEL3 and the comparison circuit CMP shown in FIG. 9A, a noise problem may occur in the same manner as in the second embodiment. The noise sneaks into the voltage to be monitored VMI (for example, the power supply voltage) through the resistance element Rd2, so that there is a risk that the noise may cause malfunction of a circuit operated by the power supply voltage. Therefore, in the same manner as in the second embodiment, it is useful to configure the voltage monitoring circuit VMNC3 with a circuit as shown in FIG. 10.

FIG. 10 is a circuit diagram showing a detailed configuration example of the voltage monitoring circuit of FIG. 9A. The voltage monitoring circuit VMNC3a shown in FIG. 10 includes a resistance element Rd2 and a comparison circuit CMP3, and the comparison circuit CMP3 includes a selection circuit SEL1c. However, the comparison circuit CMP3 is different from the comparison circuit CMP2, and the comparison circuit CMP3 does not include the NMOS transistor MN2 of FIG. 12, but includes three NMOS transistors MN2t, MN2n, and MN2b instead of the NMOS transistor MN2. Drain nodes of the NMOS transistors MN2t, MN2n, and MN2b are coupled in common. The NMOS transistor MN2t is driven by the voltage to be monitored VMI_T for self-diagnosis, the NMOS transistor MN2n is driven by the voltage to be monitored VMI_N for normal use, and the NMOS transistor MN2b is driven by the voltage to be monitored VMI_B for boost.

The selection circuit SEL1c includes three switches SWt, SWn, and SWb (here, they are NMOS transistors). One ends of the three switches SWt, SWn, and SWb are coupled in common, and the other ends are coupled to the three NMOS transistors MN2t, MN2n, and MN2b, respectively. In other words, the three switches SWt, SWn, and SWb are inserted into current paths of the three NMOS transistors MN2t, MN2n, and MN2b, respectively. The size relationship of FIG. 8 can be applied to transistor sizes of the three NMOS transistors MN2t, MN2n, and MN2b and the three switches (NMOS transistors) SWt, SWn, and SWb.

### <<Main Effects of Third Embodiment>>

As described above, when the voltage monitoring circuit and the semiconductor device of the third embodiment are used, it is possible to obtain the various effects described in the first embodiment and the second embodiment even when the voltage to be monitored VMI is high. Here, a case that detects the lower limit specification violation is described as an example. However, of course, in the same manner as in the first embodiment, it is possible to detect the upper limit specification violation or both the upper and lower limit specification violations.

While the invention made by the inventors has been specifically described based on the embodiments, the present invention is not limited to the embodiments and may be variously modified without departing from the scope of the invention. For example, the above embodiments are described in detail in order to describe the present invention in an easily understandable manner, and the embodiments are not necessarily limited to those that include all the components described above. Further, some components of a certain embodiment can be replaced by components of another embodiment, and components of a certain embodiment can be added to components of another embodiment. Further, regarding some components of each embodiment, it is possible to perform addition/deletion/exchange of other components.

### APPENDIX

A semiconductor device composed of one semiconductor chip, the semiconductor device comprising:

a voltage monitoring circuit that detects a presence or absence of a specification violation of a voltage to be monitored by comparing the voltage to be monitored with a determination threshold voltage and can output a detection result indicating that there is a specification violation in response to a request when a self-diagnosis is performed;

a self-diagnosis control circuit that controls the voltage monitoring circuit; and

a reference voltage generation circuit that generates the determination threshold voltage,

wherein the voltage monitoring circuit includes

a resistance element that generates a first voltage to be monitored, a second voltage to be monitored, and a third voltage to be monitored by resistance-dividing the voltage to be monitored,

a selection circuit that selects any one of the first voltage to be monitored, the second voltage to be monitored, and the third voltage to be monitored, and

a comparison circuit that detects the presence or absence of the specification violation by comparing a selected voltage selected by the selection circuit and the determination threshold voltage,

wherein the self-diagnosis control circuit controls the selection circuit when the self-diagnosis is performed and thereby causes the selection circuit to define the first voltage to be monitored as an initial state and sequentially select the second voltage to be monitored, the third voltage to be monitored, and the first voltage to be monitored,

wherein the second voltage to be monitored is a voltage having a polarity reverse to that of the first voltage to be monitored with reference to the determination threshold voltage, and

wherein the third voltage to be monitored is a voltage having the same polarity as that of the first voltage to be monitored with reference to the determination threshold voltage and has a potential difference larger than that of the first voltage to be monitored.

What is claimed is:

1. A voltage monitoring circuit that detects a presence or absence of a specification violation of a voltage to be monitored by comparing the voltage to be monitored with a first determination threshold voltage and can output a detection result indicating that there is a specification violation in response to a request when a self-diagnosis is performed, the voltage monitoring circuit comprising:
a selection circuit that selects any one of the first determination threshold voltage, a second determination threshold voltage that is a voltage having a polarity reverse to that of the first determination threshold voltage with reference to the voltage to be monitored, and a third determination threshold voltage that is a voltage having the same polarity as that of the first determination threshold voltage with reference to the voltage to be monitored and has a potential difference larger than that of the first determination threshold voltage; and
a comparison circuit that detects the presence or absence of the specification violation by comparing a selected voltage selected by the selection circuit and the voltage to be monitored,
wherein when the self-diagnosis is performed, the selection circuit defines the first determination threshold voltage as an initial state and sequentially selects the second determination threshold voltage, the third determination threshold voltage, and the first determination threshold voltage.

2. The voltage monitoring circuit according to claim 1,
wherein the comparison circuit has a differential amplifier circuit including a first transistor and a second transistor which are differential pair transistors,
wherein the first transistor is driven by the selected voltage, and
wherein the second transistor is driven by the voltage to be monitored.

3. The voltage monitoring circuit according to claim 2,
wherein the first transistor includes a first A transistor, a first B transistor, and a first C transistor, whose one ends are coupled in common,
wherein the first A transistor is driven by the first determination threshold voltage,
wherein the first B transistor is driven by the second determination threshold voltage,
wherein the first C transistor is driven by the third determination threshold voltage, and
wherein the selection circuit has
a first A switch that is inserted into a current path of the first A transistor,
a first B switch that is inserted into a current path of the first B transistor, and
a first C switch that is inserted into a current path of the first C transistor.

4. The voltage monitoring circuit according to claim 3,
wherein a size of the first A transistor is the same as a size of the second transistor, and
wherein a size of the first B transistor or the first C transistor is smaller than the size of the first A transistor.

5. The voltage monitoring circuit according to claim 3,
wherein a size of the first A transistor is the same as a size of the second transistor, and
wherein sizes of the first B transistor and the first C transistor are smaller than the size of the first A transistor.

6. The voltage monitoring circuit according to claim 5,
wherein the size of the first C transistor is smaller than the size of the first B transistor.

7. The voltage monitoring circuit according to claim 1,
wherein as the first determination threshold voltages, a first A determination threshold voltage having a potential lower than that of the voltage to be monitored and a first B determination threshold voltage having a potential higher than that of the voltage to be monitored are provided, and
wherein the selection circuit and the comparison circuit have
a first selection circuit and a first comparison circuit that detect whether or not the voltage to be monitored falls below the first A determination threshold voltage based on the first A determination threshold voltage, and
a second selection circuit and a second comparison circuit that detect whether or not the voltage to be monitored rises above the first B determination threshold voltage based on the first B determination threshold voltage.

8. A voltage monitoring circuit that detects a presence or absence of a specification violation of a voltage to be monitored by comparing the voltage to be monitored with a determination threshold voltage and can output a detection result indicating that there is a specification violation in response to a request when a self-diagnosis is performed, the voltage monitoring circuit comprising:
a resistance element that generates a first voltage to be monitored, a second voltage to be monitored, and a third voltage to be monitored by resistance-dividing the voltage to be monitored;
a selection circuit that selects any one of the first voltage to be monitored, the second voltage to be monitored, and the third voltage to be monitored; and
a comparison circuit that detects the presence or absence of the specification violation by comparing a selected voltage selected by the selection circuit and the determination threshold voltage,
wherein when the self-diagnosis is performed, the selection circuit defines the first voltage to be monitored an initial state and sequentially selects the second voltage to be monitored, the third voltage to be monitored, and the first voltage to be monitored,
wherein the second voltage to be monitored is a voltage having a polarity reverse to that of the first voltage to be monitored with reference to the determination threshold voltage, and
wherein the third voltage to be monitored is a voltage having the same polarity as that of the first voltage to be monitored with reference to the determination threshold voltage and has a potential difference larger than that of the first voltage to be monitored.

9. The voltage monitoring circuit according to claim 8,
wherein the comparison circuit has a differential amplifier circuit including a first transistor and a second transistor which are differential pair transistors,
wherein the first transistor is driven by the determination threshold voltage, and
wherein the second transistor is driven by the selected voltage.

10. The voltage monitoring circuit according to claim 9,
wherein the second transistor includes a second A transistor, a second B transistor, and a third C transistor, whose one ends are coupled in common,
wherein the second A transistor is driven by the first voltage to be monitored,
wherein the second B transistor is driven by the second voltage to be monitored,
wherein the second C transistor is driven by the third voltage to be monitored, and
wherein the selection circuit has
a second A switch that is inserted into a current path of the second A transistor,
a second B switch that is inserted into a current path of the second B transistor, and
a second C switch that is inserted into a current path of the second C transistor.

11. The voltage monitoring circuit according to claim 10,
wherein a size of the second A transistor is the same as a size of the first transistor, and
wherein a size of the second B transistor or the second C transistor is smaller than the size of the second A transistor.

12. The voltage monitoring circuit according to claim 10,
wherein a size of the second A transistor is the same as a size of the first transistor, and
wherein sizes of the second B transistor and the second C transistor are smaller than the size of the second A transistor.

13. The voltage monitoring circuit according to claim 12,
wherein the size of the second C transistor is smaller than the size of the second B transistor.

14. A semiconductor device composed of one semiconductor chip, the semiconductor device comprising:
a voltage monitoring circuit that detects a presence or absence of a specification violation of a voltage to be monitored by comparing the voltage to be monitored with a first determination threshold voltage and can output a detection result indicating that there is a specification violation in response to a request when a self-diagnosis is performed;
a self-diagnosis control circuit that controls the voltage monitoring circuit; and
a reference voltage generation circuit that generates the first determination threshold voltage, a second determination threshold voltage that is a voltage having a polarity reverse to that of the first determination threshold voltage with reference to the voltage to be monitored, and a third determination threshold voltage that is a voltage having the same polarity as that of the first determination threshold voltage with reference to the voltage to be monitored and has a potential difference larger than that of the first determination threshold voltage,
wherein the voltage monitoring circuit includes
a selection circuit that selects any one of the first determination threshold voltage, the second determination threshold voltage, and the third determination threshold voltage, and
a comparison circuit that detects the presence or absence of the specification violation by comparing a selected voltage selected by the selection circuit and the voltage to be monitored, and
wherein the self-diagnosis control circuit controls the selection circuit when the self-diagnosis is performed and thereby causes the selection circuit to define the first determination threshold voltage as an initial state and sequentially select the second determination threshold voltage, the third determination threshold voltage, and the first determination threshold voltage.

15. The semiconductor device according to claim 14,
wherein the comparison circuit has a differential amplifier circuit including a first transistor and a second transistor which are differential pair transistors,
wherein the first transistor is driven by the selected voltage, and
wherein the second transistor is driven by the voltage to be monitored.

16. The semiconductor device according to claim 15,
wherein the first transistor includes a first A transistor, a first B transistor, and a first C transistor, whose one ends are coupled in common,
wherein the first A transistor is driven by the first determination threshold voltage,
wherein the first B transistor is driven by the second determination threshold voltage,
wherein the first C transistor is driven by the third determination threshold voltage, and
wherein the selection circuit has
a first A switch that is inserted into a current path of the first A transistor,
a first B switch that is inserted into a current path of the first B transistor, and
a first C switch that is inserted into a current path of the first C transistor.

17. The semiconductor device according to claim 16,
wherein a size of the first A transistor is the same as a size of the second transistor, and
wherein sizes of the first B transistor and the first C transistor are smaller than the size of the first A transistor.

18. The semiconductor device according to claim 14,
wherein a plurality of the voltage monitoring circuits are provided according to a plurality of the voltages to be monitored.

19. The semiconductor device according to claim 14,
wherein the voltage to be monitored is a power supply voltage supplied from outside the semiconductor device.

20. The semiconductor device according to claim 14,
wherein the self-diagnosis is preformed when the semiconductor device is started.
